(19) United States
(12) Patent Application Publication
(10) Pub. No.: US 2018/0145625 A1
(43) Pub. Date: May 24, 2018

(54) HYBRID SUBSTRATE THAT FACILITATES DROPWISE CONDENSATION

(71) Applicants: Research Foundation of the City University of New York, New York, NY (US); ARL Designs LLC, New Providence, NJ (US)

(72) Inventors: Alan M. Lyons, New Providence, NJ (US); QianFeng Xu, Staten Island, NY (US)

(21) Appl. No.: 15/821,318

(22) Filed: Nov. 22, 2017

Related U.S. Application Data
(60) Provisional application No. 62/425,245, filed on Nov. 22, 2016.

(51) Int. Cl. H02S 40/10; C09D 5/00; C09D 201/00; H01L 31/048

(52) U.S. Cl. CPC H02S 40/10; H01L 31/0481; C09D 201/00; C09D 5/00

(57) ABSTRACT

A hybrid substrate is provided that facilitates dropwise condensation and self-cleaning. The substrate has hydrophilic regions surrounded by hydrophobic regions. Water preferentially condenses on the hydrophilic regions. The hydrophilic regions are arranged to promote removal of the condensed water.

### CROSS-REFERENCE TO RELATED APPLICATIONS

This application claims priority to and is a non-provisional of U.S. Patent Application 62/425,245 (filed Nov. 22, 2016), the entirety of which is incorporated herein by reference.

### BACKGROUND OF THE INVENTION

The subject matter disclosed herein relates to self-cleaning coatings. Many commercial applications benefit from self-cleaning technology. For example, solar panels often suffer performance problems due to dust accumulation. Manual cleaning may be performed but each iteration of cleaning risks damaging the panel. It would therefore be desirable to utilize self-cleaning technology, such as self-cleaning polymer films.

Polymer films possessing multi-functional properties, such as transparency, anti-reflectivity, superhydrophobicity and self-cleaning properties, have many important applications ranging from small digital micro-fluid devices and precise optical components to large implementations such as display screen, solar panels and building materials. Generally transparency and superhydrophobicity are two competitive properties. Superhydrophobicity and the derived self-cleaning properties utilize hierarchical micro/nano structures with high surface roughness. However, the high roughness can cause significant light scattering that reduces transparency. By controlling the surface roughness to be less than approximately 150 nm and maintaining a high ratio of air to solid interface, superhydrophobicity and transparency in the visible region of the spectrum can be simultaneously achieved. Additionally, in order to simultaneously implement anti-reflective (AR) properties in visible region of the spectrum using surface structures, one must ensure the nanopores on the surface are smaller than the wavelength and arranged in a gradient distribution so that the refractive index of the surface varies gradually from the bulk material to air.

Self-cleaning technology also improves the efficiency of many cooling devices and reduces water consumption. The magnitude of water consumption by thermal power stations (40% of total U.S. freshwater withdrawals) is non-sustainable and electric utilities need condenser technologies with improved efficiency. HVAC consumes 5% of the electricity generated in the USA and demand is increasing at 600 TWh/yr worldwide. For these heat transfer applications a metal surface is presented to a vapor phase. Heat is transferred from the vapor to the metal at the metal interface. The metal then conducts the heat to another fluid (e.g. cooling water or the evaporator side of a vapor-compression refrigeration system). A series of parallel metal fins is typically used for this application as shown in FIG. 1A. High humidity levels and surface temperatures below the dew point, cause a layer of liquid water to condense onto the metal surface as shown in FIG. 1B. Water is a thermal insulator, and the liquid film acts as a thermal barrier to heat transfer, decreasing the efficiency of the heat-transfer surface. The discussion above is merely provided for general background information and is not intended to be used as an aid in determining the scope of the claimed subject matter.

Metal surfaces have been chemically modified to achieve dropwise condensation (DWC), but these thin, monolayer coatings or copper oxide coatings, wear-away quickly. Polymer coatings offer greater reliability, but the coating thickness creates a significant thermal resistance. Polyethylene composites with silica nanoparticles are relatively thick, typically greater than 10 μm and frequently greater than 50 μm. This thickness of polymer creates a thermal bather and reduces heat transfer efficiency. Thin polymer coatings prepared by physical vapor deposition methods are robust, but are expensive and droplet removal rate is slow. Superhydrophobic surfaces exhibit high water removal rates, but the liquid transitions to filmwise condensation over time. As shown in FIG. 1C, if a metal surface is modified to be sufficiently hydrophobic, the liquid water condenses in the form of droplets which will roll-off the surface before coalescing into a film. Thus dropwise condensation leaves the metal surface exposed resulting in enhanced heat transfer.

Techniques to prepare such advanced multi-functional surfaces typically involves multiple steps, expensive equipment, releasing of toxic chemicals and are limited to small and flat areas. Developing new methods that are low-cost, environmental friendly and compatible with industrial roll-to-roll manufacturing processes to make such multifunctional surfaces would be industrially significant.

### BRIEF DESCRIPTION OF THE INVENTION

A hybrid substrate is provided that facilitates dropwise condensation and self-cleaning. The substrate has hydrophilic regions surrounded by hydrophobic regions. Water preferentially condenses on the hydrophilic regions. The hydrophilic regions are arranged to promote removal of the condensed water.

In a first embodiment, a hybrid substrate that has both hydrophobic and hydrophilic regions is provided. The hybrid substrate comprising: a planar substrate having a first surface; a plurality of hydrophilic surfaces on the first surface, wherein each hydrophilic surface in the plurality of hydrophilic surfaces is spaced from adjacent hydrophilic surfaces by a hydrophobic surface with a pitch and the hydrophobic surface has a contact angle of at least 90°; wherein the planar substrate, the plurality of hydrophilic surfaces and the hydrophobic surface are all optically transparent such that the hybrid substrate has at least 91% transmittance at 550 nm.

In a second embodiment, a hybrid substrate that has both hydrophobic and hydrophilic regions is provided. The hybrid substrate comprising: a planar glass substrate having a first surface and a second surface opposite the first surface; a plurality of hydrophilic surfaces on the first surface, wherein each hydrophilic surface in the plurality of hydrophilic surfaces is spaced from adjacent hydrophilic surfaces by a hydrophobic surface with a contact angle of at least 90°; wherein the planar substrate, the plurality of hydrophilic surfaces and the hydrophobic surface are all optically transparent such that the hybrid substrate has at least 91% transmittance at 550 nm; and a photovoltaic cell disposed proximate the second surface.

In a third embodiment, an optically transparent substrate is provided. The optically transparent substrate comprising: an optically transparent first substrate having a first surface with a plurality of optically transparent bumps, the plurality of optically transparent bumps having an average bump pitch, an average bump diameter and an average bump height, and an aspect ratio (height:diameter) given by a ratio of the average bump height to the average bump diameter; an optically transparent semi-crystalline thermoplastic material having a coating thickness disposed on, and contiguous with, both the first surface and the plurality of optically transparent bumps, wherein the average bump height is greater than the coating thickness; wherein the optically transparent semi-crystalline thermoplastic material comprises a fluropolymer having a water contact angle greater than 110°.

One application for this this technology is solar cover glass for photovoltaic panels as well as architectural glass and windows and lenses for sensors. Other applications for this technology include steam condensers in thermal electric power generation plants and in air conditioning units in HVAC systems. New applications such as thermoelectric zonal cooling and water harvesting at drilling rigs present additional opportunities for efficient cooling solutions. By fabricating condensers with the proposed coating, cooling efficiency will be increased through dropwise condensation which will lower operating costs and reduce CO₂ emissions.

This brief description of the invention is intended only to provide a brief overview of subject matter disclosed herein according to one or more illustrative embodiments, and does not serve as a guide to interpreting the claims or to define or limit the scope of the invention, which is defined only by the appended claims. This brief description is provided to introduce an illustrative selection of concepts in a simplified form that are further described below in the detailed description. This brief description is not intended to identify key features or essential features of the claimed subject matter, nor is it intended to be used as an aid in determining the scope of the claimed subject matter. The claimed subject matter is not limited to implementations that solve any or all disadvantages noted in the background.

### BRIEF DESCRIPTION OF THE DRAWINGS

So that the manner in which the features of the invention can be understood, a detailed description of the invention may be had by reference to certain embodiments, some of which are illustrated in the accompanying drawings. It is to be noted, however, that the drawings illustrate only certain embodiments of this invention and are therefore not to be considered limiting of its scope, for the scope of the invention encompasses other equally effective embodiments. The drawings are not necessarily to scale, emphasis generally being placed upon illustrating the features of certain embodiments of the invention. In the drawings, like numerals are used to indicate like parts throughout the various views. Thus, for further understanding of the invention, reference can be made to the following detailed description, read in connection with the drawings in which:

FIG. 1A is a profile view of multiple cooling fins; FIG. 1B is a profile view showing water accumulation on the cooling fins; FIG. 1C is a profile view illustrating dropwise condensation;

FIG. 2A is a face view of a substrate with hydrophobic and square hydrophilic regions; FIG. 2B is a face view of a substrate with hydrophobic and triangular hydrophilic regions; FIG. 2C is a face view of a substrate with hydrophobic and tad-poll shaped hydrophilic regions;

FIG. 3A, FIG. 3B and FIG. 3C are face views of substrates with staggered arrays of hydrophilic regions;

FIG. 4A, FIG. 4B and FIG. 4C are cross section views of substrates showing different vertical profiles of the hydrophilic regions;

FIG. 5A, FIG. 5B, FIG. 5C and FIG. 5D are cross section views of substrates showing different vertical profiles of the hydrophilic regions;

FIG. 6A, FIG. 6B and FIG. 6C are face views showing various configurations of continuous linear hydrophilic regions;

FIG. 7A, FIG. 7B and FIG. 7C are cross section views of substrates showing different vertical profiles of the hydrophilic regions;

FIG. 8 is a depiction of hydrophilic regions formed by removal of hydrophobic regions;

FIG. 9 shows an electrowetting method that can affect the contact angle between a liquid and solid surface;

FIG. 10 depicts a method for forming a hybrid substrate by depositing beads;

FIG. 11 shows the effect of bead pitch on abrasion of the hydrophobic region;

FIG. 12 depicts one method for cleaning a solar power panel that has a hybrid glass surface;

FIG. 13 depicts another method for cleaning a solar power panel that has a hybrid glass surface;

FIG. 14 depicts the formation of a water ridge; and

FIG. 15 depicts water condensing preferentially on the hydrophilic regions.

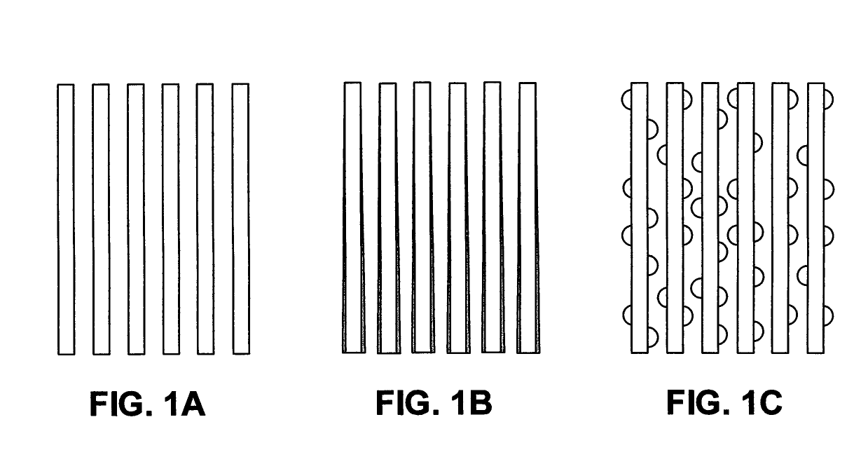

### DETAILED DESCRIPTION OF THE INVENTION

A paper entitled “Design and Fabrication of a Hybrid Superhydrophobic-Hydrophilic Surface That Exhibits Stable Dropwise Condensation” (ACS Appl. Mater. Interfaces 2015, 7, 23575-23588) describes a hybrid surface with a superhydrophobic polymer is impaled by a series of sharp protrusions (e.g. needles), while highly effective, is more expensive to fabricate and difficult to incorporate into many designs (e.g. solar cover glass coatings and thin aluminum fin heat-sinks for HVAC). An array of hydrophilic needles, thermally connected to a heat sink, was forced through a robust superhydrophobic polymer film. Condensation occurs preferentially on the needle surface due to differences in wettability and temperature. As the droplet grows, the liquid drop on the needle remains in the Cassie state and does not wet the underlying superhydrophobic surface. The water collection rate on this surface was studied using different surface tilt angles, needle array pitch values and needle heights. Water condensation rates on the hybrid surface were shown to be four times greater than for a planar copper surface and twice as large for silanized silicon or superhydrophobic surfaces without hydrophilic features. A convection-conduction heat transfer model was developed; predicted water condensation rates were in good agreement with experimental observations.

Although this surface exhibited stable dropwise condensation, there are several challenges to overcome before this approach could be used on solar cover glass or common heat transfer surfaces such as heat sinks and steam condenser systems. These include (1) Temperature Drop: Because the needles have a high aspect ratio, they create a thermal resistance between the heat conducting surface and the vapor. Thermal efficiency is decreased because of the resulting temperature drop across the needles. (2) Contact Line Length: Because the needles are relatively large, about 75 μm diameter and 200 μm tall, the vapor-liquid-solid triple contact line is relatively long. This results in a higher tilt angle and/or a larger droplet mass accumulation before the droplet can roll-off (critical droplet volume). Reducing the size of the hydrophilic region would reduce the critical droplet volume for roll-off and thus increase heat transfer rates. (3) Thermal insulation: Insulating the superhydrophobic polymer from the heat sink shifted most of the condensation to the hydrophilic needles. By creating a system with a thin dielectric, bonded directly to the metal heat transfer surface, more water would be condensed on the superhydrophobic surface. This would increase the overall heat transfer efficiency of the surface. (4) Fabrication costs: Thermally bonding arrays of high aspect ratio metal features (e.g. needles) to the heat transfer surface can be costly and difficult to scale.

This disclosure provides both a self-cleaning and/or heat transfer surface as well as the process for creating the surface. As described elsewhere in this disclosure, a hybrid hydrophobic-hydrophilic surface has been shown to exhibit enhanced heat transfer efficiency compared to pure metal as well as a hydrophobic surfaces alone. To further increase anti-soiling efficiency, and/or water collection efficiency and/or heat transfer efficiency, while minimizing fabrication costs, several new approaches have been developed and are disclosed herein.

In one embodiment, a method for producing a hybrid surface is disclosed. The first step in the method is to apply a thin polymer coating onto a planar substrate. Examples of planar substrates include glass with high optical transparency (e.g. greater than 90% transmittance at 550 nm). In one embodiment, the glass has an optical transparency greater than 91.0% at 550 nm and is suitable for use in solar panels. Alternatively, a metal substrate may be used. For example, an aluminum sheet that measures 0.2-0.5 mm thick is coated with a thin polymer surface as disclosed in U.S. Patent Publication US2016/0332415. The polymer coating may be hydrophobic (contact angle of greater than 90°) with a low contact angle hysteresis (difference between advancing and receding contact angle) in the range of 0.1° and 50° or a surface that has a small sliding angle for a droplet to slide off when the substrate is tilted (0.1° and 50°). Alternatively, the polymer surface can be made to be superhydrophobic with a contact angle greater than 150° and a sliding angle of less than 50°. The polymer coating should be as thin as possible, but less than 10 microns and, in some embodiments, less than 1 micron thick. To promote dropwise condensation, the surface should either be very smooth, or sufficiently rough to stabilize liquid water in the superhydrophobic (i.e. Cassie) state. In some embodiments, the polymer coating is optically transparent. A smooth surface, with a root mean square (RMS) roughness of less than 5 nm, is preferred in some applications because the surface exhibits greater abrasion resistance. Here abrasion resistance can be defined as the optical percent transmission properties of the surface are degraded by less than 0.5% after 500 strokes during a reciprocating abraser test similar to specification EN1096.2. A rougher surface, one with a RMS roughness of greater than 20 nm, may be subject to greater degradation of anti-reflective properties during abrasion testing. Changes to coating properties would be especially large if changes in contact angle were considered. A surface with surface roughness of, say, 40 nm is superhydrophobic with a contact angle of 148°, however, this contact angle could be reduced to 100° after abrasion testing. This change is much greater than 5%, but changes to the anti-reflective or anti-soiling properties may not be reduced by more than 5%.

The polymer for the coating can be any thermoplastic (e.g. PVF (polyvinylfluoride), PVDF (polyvinylidene fluoride), PTFE (polytetrafluoroethylene), PCTFE (polychlorotrifluoroethylene), PFA (perfluoroalkoxy polymer), FEP (fluorinated ethylene-propylene), ETFE (polyethylenetetrafluoroethylene), ECTFE (polyethylenechlorotrifluoroethylene), FFPM/FFKM (Perfluorinated Elastomer [Perfluoroelastomer]), FPM/FKM (Fluorocarbon [Chlorotrifluoroethylenevinylidene fluoride]), FEPM (Fluoroelastomer [Tetrafluoroethylene-Propylene]), PFPE (Perfluoropolyether), PFSA (Perfluorosulfonic acid), Perfluoropolyoxetane) or thermosetting polymer (e.g. polydimethylsiloxane or PDMS) so long as the polymer thickness is sufficiently thin and the sliding angle of water on the surface is sufficiently low (<50°, or <20°, or <10°) and good adhesion to the substrate is maintained under operating conditions. The low sliding angles indicate that chemical interactions between the surface and liquid water are minimal, a condition known as low surface energy. The polymers should also exhibit good chemical stability so that they do not oxidize over time at the use temperature. This is especially important for solar cover glass applications where coatings are exposed to ultraviolet (UV) light and high temperatures and steam condenser applications where the high temperatures and pressures can oxidize most polymers. The polymers should also be thermally stable under use conditions, for long periods of time (greater than 10 years and more preferably greater than 20 years or 30 years) as well as subsequent fabrication steps, such as welding and soldering. Fluoropolymers and PDMS are all known to exhibit excellent UV, chemical and thermal stability.

U.S. Patent Publication US2016/0332415 discloses a suitable thin superhydrophobic coating. This can coat glass or a heat transfer surface such that dropwise condensation will be enhanced and cooling efficiency increased by more than fourfold. This coating exhibits several advantages including: (1) Thin Coating with a thickness of less than 1 micron that is optically transparent and anti-reflective and imposes minimal thermal resistance (e.g. less than 1 degree Centigrade per Watt), thereby reducing temperature drop across the thermally insulating coating thus increasing overall thermal efficiency (2) Robust Polymer comprised of a high molecular weight polymer (e.g. a polymer with a molecular weight that is at least 10,000 Da and more preferably greater than 20,000 Da, 50,000 Da, 100,000 Da) that provides greater mechanical durability compared to small-molecule coatings that are commonly used.

In one embodiment a second step is used to form an array of hydrophilic regions on the coated surface where the water contact angle of the hydrophilic regions are <90° and more preferably <75°, <50°, <40°, <20°. In one embodiment, the hydrophilic regions are optically transparent. Hydrophilic regions are defined in the coating that cause water to rapidly nucleate and grow into droplets that exceed the critical size for roll-off. These hydrophilic regions are fabricated by various methods. The thin hydrophobic polymer coating, alone, is sufficient to promote stable DWC and improved heat transfer efficiency. However, the addition of hydrophilic regions may provide a further enhancement to performance. Water will nucleate liquid droplets much more rapidly on a hydrophilic surface than on a hydrophobic surface. In addition, since the vapor pressure of liquid water depends upon the radius of curvature of the liquid water droplet, condensation will occur at a faster rate on larger diameter droplets as compared to smaller diameter droplets. Thus as nucleation progresses, the growth rate of larger droplets will be accelerated at the expense of smaller droplets who's growth will be slowed by their relatively higher evaporation rate. The Kelvin equation describes this change in vapor pressure as a function of the curvature of the liquid-vapor interface.

The third step in the process is to form the coated substrate into the desired shape. For example a coated sheet can be formed into fins of the appropriate size, by punching, cutting, and/or folding. If desired, the fins can be attached to a base plate by standard processes including crimping, welding, brazing, soldering, etc. Alternatively, the coated sheet could be rolled into a tube and the seam sealed by welding or soldering. An example of a fully formed heat sink is shown in FIG. 8 where the hydrophilic regions were created by drilling.

When warm humid air contacts the coated surface, moisture in the air will cool below the dew point and condense preferentially on the hydrophilic regions formed on the coated surface. Heat released during condensation conducts through the coating and substrate. As condensation proceeds, the droplets grow in size, especially on the hydrophilic regions. Additional droplets will form on the hydrophobic coating. However, most of these droplets will remain smaller than the droplets formed on the hydrophilic regions. Some droplets formed on the hydrophilic regions may contact droplets nucleated on hydrophobic regions, either because the two droplets grow into each other, or because the size of one droplet exceeds the critical droplet volume on the coating and rolls into the stationary drop. When the droplets contact, they merge and remain centered on the hydrophilic region, resulting in faster grow rates. Eventually, these droplets on the hydrophilic regions exceed the critical volume and roll off the surface, imbibing all droplets in their path along the downward slope.

For some embodiments, the best orientation for this surface is normal to the ground (90°), which would maximize the gravitational force. However, any tilt angle will improve performance compared to a surface that is coplanar with the ground (0°). In one embodiment, the orientation is between 10° and 80°. It may be desirable to create additional channels in the system to carry the condensed water from the cover glass or heat transfer surface to a liquid sink, or conduit so that the water can be recycled, stored, or removed for future use.

One consideration is the length of the triple contact line (TCL) that occurs at the solid-liquid-vapor interface. The longer the TCL, the greater the force for the droplet to be displaced. Thus a longer TCL utilizes a larger droplet volume, a higher tilt angle, or the addition of greater amounts of external energy (e.g. vibrations, electrical stimulation, etc.) to reach the critical volume necessary for the droplet to roll-off the surface. The larger the critical droplet volume for roll-off, the lower the condensation rate and the lower the self-cleaning and heat transfer efficiency. Thus techniques to reduce the triple contact length, especially along the receding contact line, are highly desirable. To promote roll-off, the length of the receding triple contact line should be less than half the circumference of a droplet on a surface with a contact angle of 90°.

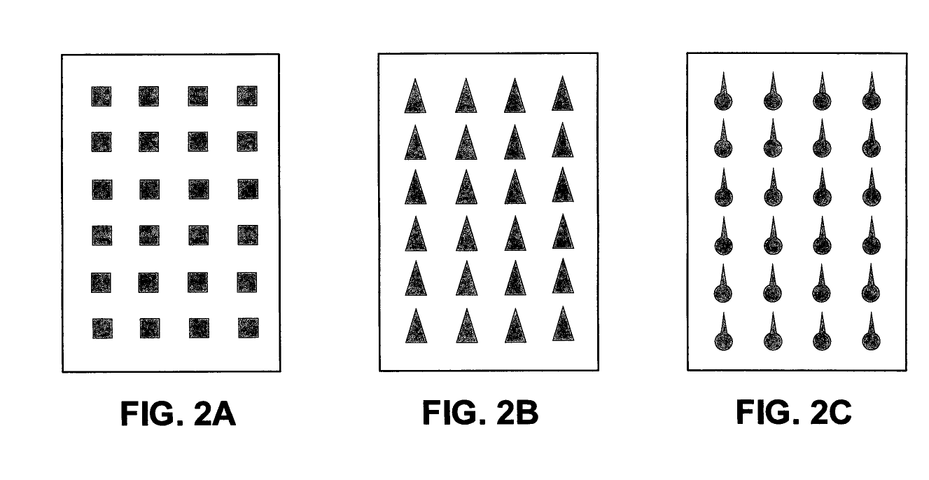

One approach to reducing the TCL is to modify the shape of the hydrophilic area. If the hydrophilic region is square shaped, as shown in FIG. 2A, then the force to displace the TCL is proportional to the length of the entire side of the square. Alternatively, if the shape of the hydrophilic region is triangular, such that the apex of the triangle is pointing toward a higher point on a slope (i.e. up-slope), as shown in FIG. 2B, then the droplet only need exceed the width of the apex before it can begin to slide. As the droplet slides downward, its advancing contact angle will increase (to >120° or >150° or >160°); the advancing contact angle depends upon the hydrophobic polymer surface. A hydrophobic surface will exhibit an advancing contact angle of about 110° whereas a superhydrophobic surface may exhibit an advancing contact angle of 165° or higher. As the droplet slides downslope, the shape of the droplet will become asymmetric due to the large contact angle hysteresis (the receding contact angle will be low because of the hydrophilicity of the region). Thus as the droplet begins to slip downslope, the center of mass of the droplet will shift downslope and it will exert a greater force on the receding TCL. This creates a virtuous cycle by which the droplet continues to slide and the force on the TCL continues to increase as the TCL elongates. As a result, the triangular shape lowers the critical volume for droplet roll-off. Other shapes may be more effective than a triangle. For example, the tadpole-like shape shown in FIG. 2C could further lower the critical droplet volume for roll-off. In this shape, the initial TCL increases very slowing, allowing the droplet to advance over the SH coating a relatively long distance. As the droplet begins to accelerate, the acceleration will exert additional force at the receding TCL such that it can eventually overcome the longest TCL at the larger diameter hydrophilic region.

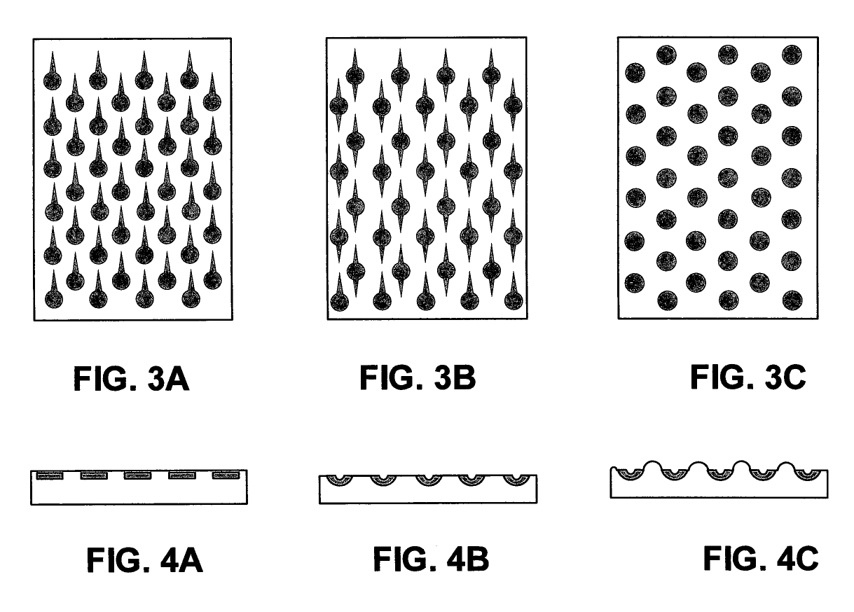

The placement and orientation of the hydrophilic regions may be varied in other ways to maximize water condensation, self-cleaning properties and heat transfer efficiency. For example, the hydrophilic regions can be formed into staggered arrays as shown in FIG. 3A. In this way, a denser array of hydrophilic regions can be formed on the coated substrate while precluding adjacent drops from contacting each other. When adjacent droplets merged, the TCL length doubled, increasing the critical roll-off volume and reducing self-cleaning and heat transfer efficiency.

In some cases, the orientation of the substrate with respect to the final device installation may not be defined. In such cases, it may be preferable if the shape is symmetrical so that it can improve droplet roll-off orientated in two different directions, as shown in FIG. 3B. The separation between (i.e. pitch) the hydrophilic regions can be adjusted such that two tails actually touch, forming a continuous hydrophilic path along the slope direction. Alternatively, each hydrophilic region can be kept separate so that any one droplet can exceed the critical volume and roll-off imbibing smaller droplets along the way. The circular shape, in FIG. 3C, has the advantage that the receding TCL is the same in all possible orientations. The pitch of hydrophilic regions may be optimized. If the pitch is too small, then droplets can merge together before they reach a critical droplet size. This is disadvantageous because the TCL is elongated, thereby using an even larger critical droplet size before roll-off can occur. However, if the pitch of the hydrophilic regions is too large, then an insufficient number of liquid droplets are formed resulting in poor condensation and self-cleaning efficiency. For example, in the case of hydrophilic needles impaled through a superhydrophobic film, the highest water collection efficiency occurred with a pitch of 1.5 mm. A pitch of 1.0 mm resulted in a 20% lower water collection rate. Similarly, a courser pitch of 3.0 mm resulted in a reduced efficiency of approximately 50%. In one embodiment, the pitch is between 0.5 mm and 10 mm. The optimal value for the pitch of the hydrophilic features will depend on the size and shape of these features as well as the slope of the glass or metal substrate.

Alignment of hydrophilic regions in linear arrays that are parallel to the slope of the heat sink are advantageous. Any drop along this line that exceeds the critical roll-off volume will begin to roll down the slope and encounter another droplet of sub-critical volume. The combination of the two droplets will exceed the critical volume and continue rolling off the substrate. This domino-effect will sweep the line clear of growing droplets and contribute to increased heat transfer efficiency.

The size of the hydrophilic regions will also affect TCL length and roll-off angle. Large hydrophilic regions are not desirable because as the receding TCL increases, the surface behaves more like filmwise condensation. However, hydrophilic regions that are too small are also undesirable as they will exhibit little advantage over a surface that has a continuous hydrophobic coating. Also, small size hydrophilic regions may be difficult to fabricate. Thus, in some embodiments, an intermediate size between 1 micron diameter and 5000 microns diameter is used. More preferably between 1 micron and 1000 microns diameter. In other embodiments, the area of the hydrophilic regions is between 1 square micron and 20 square millimeters or more preferably between 1 square micron and 1 square millimeter. In one embodiment, the area is less than 20 square millimeters. In another embodiment, the area is less than 1 square millimeter. The total area covered by hydrophilic regions should be less than 25% of the total glass or metal substrate, or more preferably, less than 10% of the total surface area.

The hydrophilic region may be lower than the surrounding hydrophobic or superhydrophobic coating. If the hydrophobic or superhydrophobic coating is less than 1 micron, then the height may be indented 1 micron lower than the surrounding coating as shown in FIG. 4A. The substrate could be dimpled to form either a concave or convex protrusion. In one case (concave) the hydrophilic region would be lower than the coated substrate by the amount by which the substrate is stretched downwards (FIG. 4B). This effect could be exaggerated by deforming the surrounding coated substrate in an upwards direction forming a convex ring around the concave hydrophilic substrate as shown in FIG. 4C. A potential advantage of having the hydrophilic substrate lower than the surrounding hydrophobic surface is that as the droplet grows, the contact of the droplet with surrounding hydrophobic or superhydrophobic walls would cause the droplet to assume a higher advancing contact angle along both the downslope (advancing) and upslope (receding) contact lines. This could reduce the critical droplet volume and cause the droplet to roll-off the surface at a smaller volume than on a flat surface.

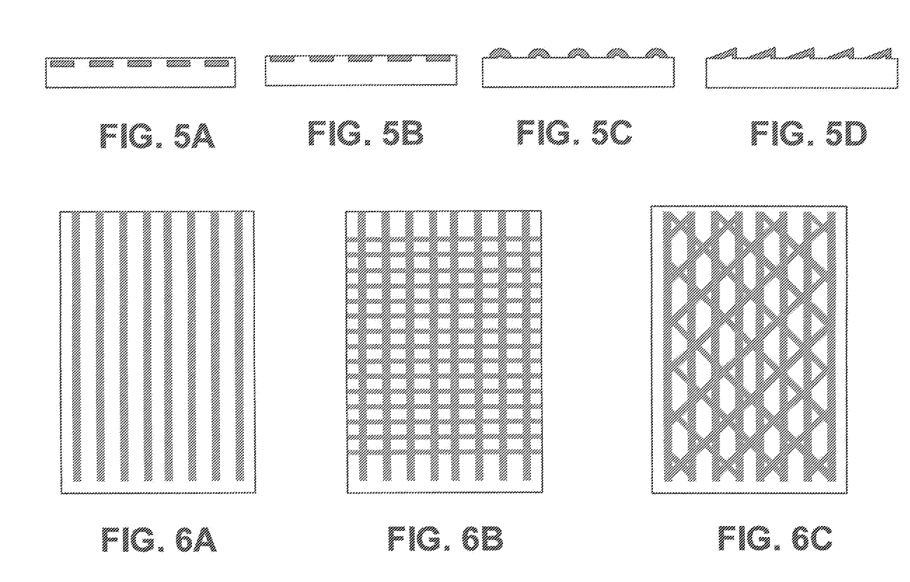

Alternatively, the substrate can be dimpled such that it becomes convex and protrudes above the hydrophobic or superhydrophobic surface as shown in FIG. 5C. In this way, as the droplet forms, the gravitational force will be aligned with the slope of the protrusion, reducing the critical size for droplet roll-off. This shape can be symmetrical so that the glass substrate or fin can be orientated in any arbitrary angle by the end user. Alternatively, the protrusions can be asymmetric (FIG. 5D) such that the slope of the hydrophilic surface is aligned with the tilt angle of the fin to enhance the gravitational force acting on the droplet, further reducing the critical droplet volume for roll-off. FIG. 5A is substantially the same as FIG. 4A but is shown alongside FIG. 5C and FIG. 5C for comparison. In FIG. 5B the hydrophilic and hydrophobic regions are coplanar.

The shape of the hydrophilic regions can be simple shapes either symmetric or asymmetric depending upon the customer needs and installation orientation. The hydrophilic regions can be either isolated or continuous. However, in some cases, it is important that a hydrophobic or superhydrophobic coating isolates the edge of the hydrophilic region from the edge of the glass substrate or fm. This coating region would prevent the accumulated water from being pinned along the edge of the substrate, making a long TCL, and thus using a large droplet volume before final roll-off.

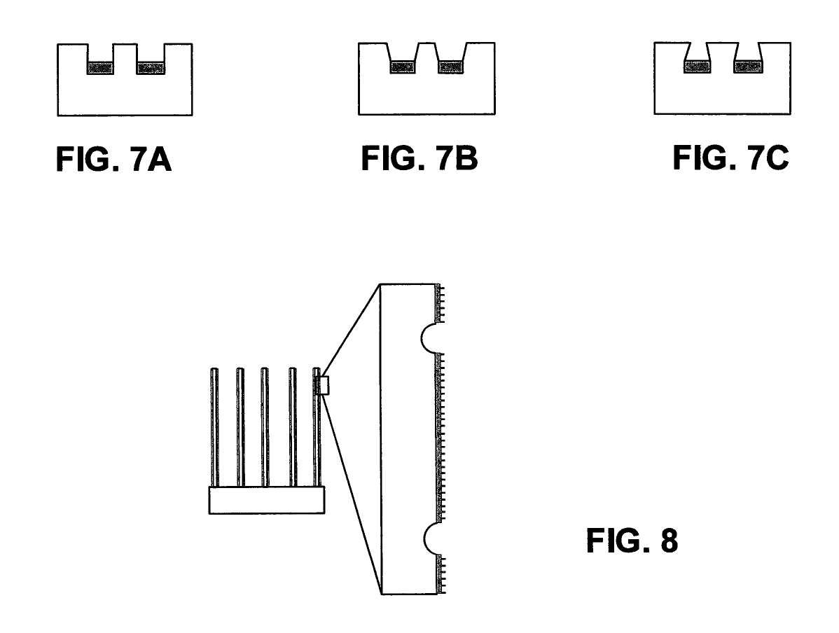

In some cases, it may be desirable to make continuous hydrophilic channels as shown in FIG. 6A to FIG. 6C. The channels can form parallel regions (FIG. 6A) that are parallel to adjacent channels, or can be comprised of an orthogonal array (FIG. 6B), or arrays of parallel regions along multiple angles (FIG. 6C). The base of the troughs is hydrophilic. The sidewalls of the regions may be either hydrophilic, hydrophobic or superhydrophobic and may have walls that are straight (FIG. 7A), sloped (FIG. 7B) or undercut as shown in (FIG. 7C). The sidewalls can be formed by stamping or machining. The percent area occupied by the hydrophilic regions should not exceed 25% of the total surface area of the substrate, otherwise filmwise condensation would become excessive and the condensation mechanism would shift towards film-wise condensation, resembling to some extent, the performance of an un-coated hydrophilic surface. In some cases the continuous hydrophilic channels may be at the same height as the surrounding hydrophobic regions, or may be even higher than the surrounding hydrophobic regions. In one embodiment, the channels have a width between 10 microns and 200 microns.

Fabrication of the hydrophilic regions on the coating can be achieved by two basic approaches: subtractive and additive.

Subtractive Fabrication: The hydrophobic polymer can be selectively removed to reveal the hydrophilic substrate below it. Suitable methods include drilling, scribing, etching, photolithography, selective exposure to a reactive plasma (e.g. through a shadow mask), corona discharge, ozone gas, laser writing, etc. One approach reveals the underlying substrate. In this case, improved performance will be obtained when the polymer coating is as thin as possible to minimize the size of the receding TCL. Also, it is desirable that adhesion between the polymer and substrate is robust and reliable so that the condensed water does not compromise this adhesive bond (i.e. between the hydrophobic coating and glass) and diffuse along the polymer-glass interface. In another approach, the polymer is not fully removed, but the surface of the polymer is chemically modified (e.g. by selective exposure to an oxygen plasma). In this case, water will not come into direct contact with the substrate and adhesion between the polymer and substrate does not risk being compromised by the mechanical removal of the polymer (e.g. by drilling).

Additive Fabrication: The selective addition of a hydrophilic material to the coating surface is a second general approach to the formation of hydrophilic regions on the coating. Techniques such as printing, dispensing and photolithography can be used to selectively add hydrophilic materials to the surface. A variety of hydrophilic materials can be added including both small molecules (e.g. silanes) as well as polymers (e.g. polymethylmethacrylate or PMMA; epoxy resins; conductive adhesives, etc.). The shape and size of the printed features will have a significant effect on critical droplet volume for roll-off as described elsewhere in this disclosure. However, additional factors must be considered for this additive deposition case because the height and shape of the hydrophilic deposit must be carefully considered. Again, the guiding principle is the minimization of the receding TCL. Thus the height should be minimized. This is especially true when the size of the feature is large enough to block or scatter visible light (i.e. for anti-soiling glass applications) or when the hydrophilic material that is deposited is a thermal insulator (i.e. for heat transfer applications). A dispensed insulator should cover the smallest possible area of coating surface so as to minimize the thermal resistance between the liquid droplet and the substrate. In addition, the shape should be optimized to minimize the critical roll-off volume. Sloped posts fabricated by dispensing a thixotropic PDMS resin using a robotic dispenser can reduce the roll-off angle for droplets along the direction of the slope. Once sufficient force acts on the droplet to displace the receding TCL at the base of the post, the droplet will roll-off completely. Because of the narrowing taper, the TCL decreases in length as the droplet moves along the post. Thus once the initial energy barrier encountered at the base is overcome, the droplet completely rolls off. In contrast, when the substrate is tilted in the opposite direction, the TCL continues to increase after the force to displace the initial TCL at the base is exceeded. Thus additional force is used (either by tilting the surface at a higher angle or increasing the volume of the droplet) for the droplet to roll-off. To minimize the length of the receding TCL as well as the scattering or thermal resistance of the system, it may be preferable to minimize the height of the hydrophilic material deposit. The main criteria is that sufficient hydrophilic material is dispensed so that the coating is mechanically robust. Moreover, reliable adhesion between the hydrophilic added material and the underlying hydrophobic coating is necessary. Modification of the underlying polymer may be necessary to insure strong adhesion. The nanotexture of a superhydrophobic coating can promote strong mechanical adhesion so long as the added hydrophilic material can wet the coating.

Additional Mechanisms to Improve DWC: It may be possible to incorporate other mechanisms to help shed droplets from the surface at lower critical droplet volumes and thus increase the heat transfer and/or water collection efficiency. In one embodiment, a mask is applied to the glass or metal substrate before a hydrophobic coating is applied. In one embodiment, this hydrophobic coating was applied from the vapor phase. For example small pieces of glass, or a concentrated aqueous solution of K₂CO₃ or a slurry of CaCO₃ in water can be applied onto the glass surface in the appropriate pattern. The masked glass sample can then be placed in a closed oven and exposed to dimethyldichlorosilane vapors such that a hydrophobic coating is formed on the exposed glass regions. The mask (e.g. small glass pieces or carbonate coating) can then be removed revealing hydrophilic, uncoated glass regions within a hydrophobic coated glass surface.

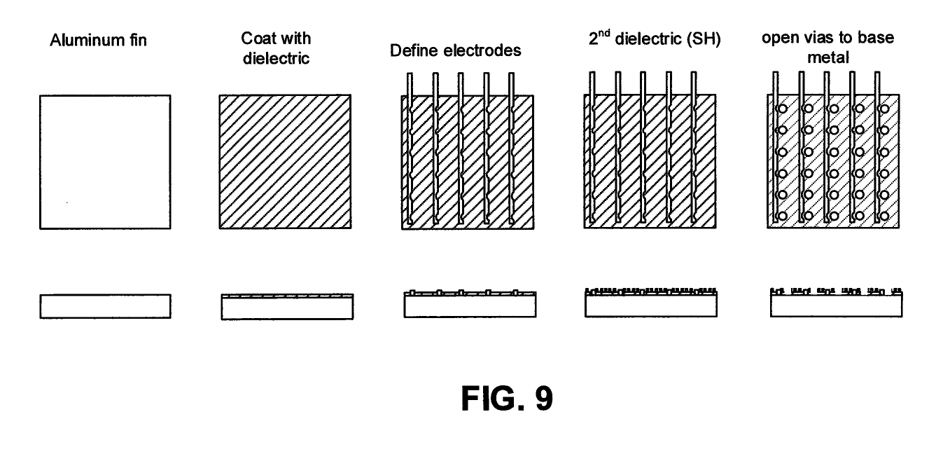

Other methods include adding energy into the system. For example, vibrations can be added to the heat sink which will be translated to the droplets allowing them to roll-off at lower sizes. Similarly, alignment of the heat sink slope with a fan or other vapor phase flow, such that the flowing gas helps promote droplet displacement. A third mechanism is electro-wetting. Electrodes can be included into the design so that an electric field can be applied between the droplet and the electrically insulating hydrophobic or superhydrophobic coating. Electrowetting is a well-known method that can affect the apparent contact angle between a liquid and solid surface. It has been used to promote the movement of droplets across hydrophobic and superhydrophobic surfaces. An example of an electro-wetting configuration is shown in FIG. 9.

In another embodiment, microbumps are used to form the hydrophilic regions. In order to impart sufficient hierarchy to the optically transparent coating, micro-bumps can be bonded to the underlying rigid (e.g. glass) substrate. In one embodiment these micro-bumps have a gradual convex shape that help to minimize reflections. The refractive index of the micro-bumps would be the same as, or lower than, the refractive index of the glass substrate to reduce reflections. To fabricate the micro-bumps on the glass surface, several approaches can be used. In one example, the glass can be cast into a mold with the appropriate pattern.

In another embodiment, a hydrophobic/hydrophilic hybrid surface with no abrupt boundaries between hydrophobic and hydrophilic regions is provided. To enhance the self-cleaning properties of a surface it is advantageous to reduce the critical size of liquid droplets that can roll-off a surface that is titled at a specific angle. Similarly, it is advantageous to reduce the angle at which a substrate is titled in order for a droplet of a specific size to roll-off. To achieve either objective, it is desirable to reduce the interactions at the receding triple contact line. As described elsewhere in this disclosure, this reduction of interactions can be achieved by modifying the size and shape of the receding TCL. Another approach to reducing the critical droplet volume and/or critical tilt angle at which droplets can roll-off the surface is to form a gradient of wetting properties between the hydrophilic and hydrophobic regions. This approach utilizes a gradual reduction in surface energy (i.e. a gradual increase in water contact angle) between the hydrophilic region that promotes water condensation and the surrounding hydrophobic region. This approach eliminates an abrupt boundary at the hydrophobic-hydrophilic interface and instead causes a gradual change in wetting properties. In one embodiment, this gradual change occurs over the entire surface of the hydrophilic area such that a central spot of the hydrophilic area exhibits the lowest contact angle and the contact angle of the surface gradually increases, radially, until the contact angle of the surface reaches the contact angle value of the hydrophobic regions. In another embodiment, a region within the hydrophilic area exhibits the same low contact angle value and the gradual increase in water contact angle occurs over a relatively short distance equivalent to one-tenth the width of the hydrophilic area. In one embodiment, the hydrophilic region is separated from the hydrophobic region by a boundary region with a width of at least 100 microns. The boundary region has a contact angle between that of the hydrophilic region and the hydrophobic region that changes over the width.

As an example, a piece of soda-lime float glass with a size of 3″×3″×⅛″ (Diamant, Saint Gobain Glass) was used as the substrate. Small pieces of the same glass were scribed to a size of 0.5″×0.5″×⅛″ and placed on the substrate to act as masks to create square hydrophilic patterns. This assembly was then exposed to a Chemical Vapor Deposition (CVD) process to create a hydrophobic coating on the glass. For example, the masked substrate could be exposed to dichlorodimethylsilane (DCDMS) in a vacuum chamber and kept for 10 minutes at 90° C. followed by several hours at room temperature. Because the glass has an ideally flat surface, the gap between the glass squares and the glass substrate was very small (less than 10 microns), so that the penetration of the DCDMS vapor and the reaction with glass was limited by diffusion such that the coating was more complete in areas where the glass was fully exposed to the vapor, but the coating became less and less complete from the edge to the center under the mask. After completion of the reaction and removal of the glass masking squares, a continuous change from hydrophobic to hydrophilic was observed in the areas under the masking pieces. Water contact angle in areas fully exposed to DCDMS vapor was greater than 100° whereas the contact angle under the center of the masked areas was less than 90°. Such a pattern enabled water droplets to slide off the hydrophilic regions of the surface smoothly and completely at lower angles relative to surfaces with an abrupt hydrophilic-hydrophobic boundary. No water residues on either the hydrophilic or hydrophobic regions remained on the gradient surface after the droplet rolled-off.

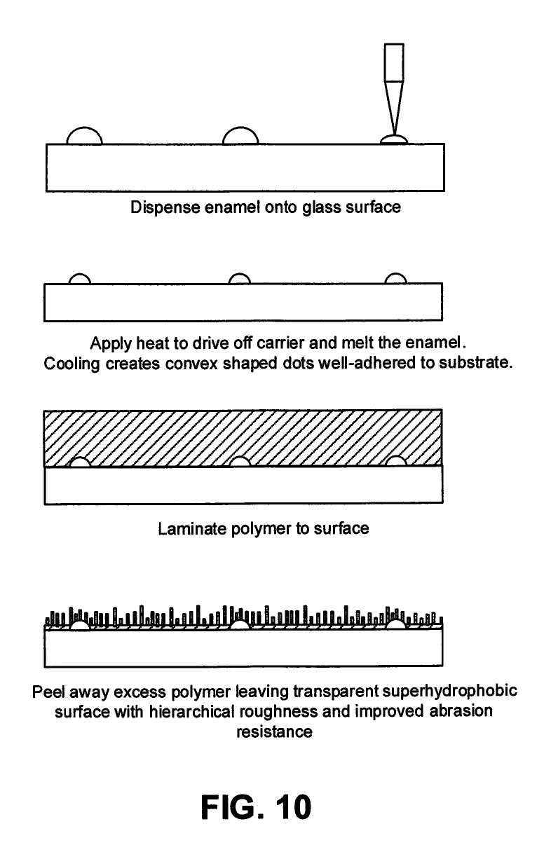

In another approach, enamel can be formulated and dispensed onto the glass substrate as shown in FIG. 10. An enamel glass precursor is formulated by dispersing enamel particles into a carrier with the proper rheological properties. The carrier would help keep particles suspended and burn-off completely during firing. Ideally, the formulation would exhibit shear thinning (also known as thixotropic) properties to facilitate dispensing and ensure that the dispensed glass did not flow excessively after being deposited on the substrate. Excessive flow would result in a final micro-bump that was not sufficiently tall above the substrate to provide adequate abrasion resistance. Broadening of the bump would also be less desirable because the bump would not be as transparent as the flat glass substrate and so the bumps should cover the smallest fraction of the area as possible.

After dispensing, the substrate with micro-bumps is heated to melt the enamel such that it flows into a smooth, convex lens shape that is well-adhered to the underlying substrate. In one embodiment the melting temperature of the enamel is lower than the melting temperature of the glass substrate. In this way, the convex shape of the micro-bumps can be achieved without distorting the overall flatness of the glass substrate. In one embodiment, the glass formed from the enamel is optically transparent with an index of refraction that is equal to or lower than the index of the glass substrate. However, since the micro-bumps are expected to be thinner than the glass substrate (approximately less than one-tenth the thickness of the substrate), the transparency of the glass formed from the enamel is not critical as it will have a relatively small impact on the overall transmission. In those cases where the micro-bumps are thicker, greater care is used in selecting an enamel system that will result in low optical losses.

After the glass micro-bump substrate has been fabricated, a superhydrophobic surface is formed on the textured substrate. For example, the technique described in U.S. Patent Publication US2016/0332415 can be used to form a transparent, anti-reflective (transmittance greater than 93.4% at 550 nm) and anti-soiling surface on the glass substrate with micro-bumps. The content of U.S. Patent Publication US2016/0332415 is hereby incorporated by reference in its entirety. As briefly summarized in FIG. 10, a polymer is laminated onto the glass at a temperature above the crystalline melt point of the polymer. After cooling below the crystalline melt point, the excess polymer is peeled away, leaving a thin, nano-textured polymer coating.

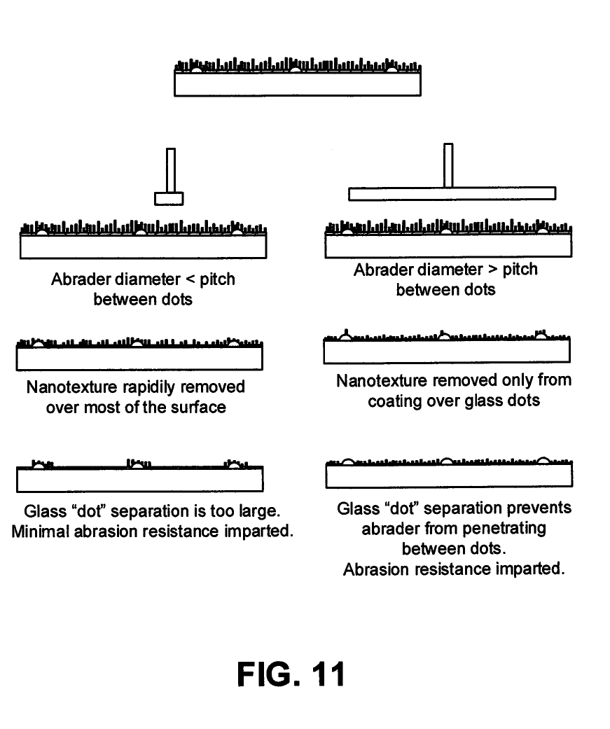

The glass precursor formulation would be dispensed or printed into an array of micro-bumps on the glass surface. The size and density of the glass micro-bumps should be kept at a minimum to ensure maximum light transmission, while the height should be at least as thick as the coating (greater than 100 nm). The diameter of the glass dots should be as small as possible, while enabling an adequate height to protect hydrophobic coating. The aspect ratio (diameter:height) should be at most 10:1, with a lower height:diameter ratio allowing for a more mechanically robust protrusion. The shape and area of the hydrophilic regions should be optimized to minimize the TCL and critical droplet roll-off size as discussed previously in this application. The density, as measured by pitch, of the posts is a variable that will be determined by the type of abrasion resistance that is desired as illustrated in FIG. 11. By spacing the micro-bumps further apart (course pitch) the impact of the glass micro-bumps on the light transmission through the glass will be minimized. Course pitch micro-bumps will provide adequate abrasion protection when the abrading surface is large and flat as illustrated in the right hand sequence in FIG. 11. For example, structures on a 10 mm pitch will protect the underlying surface from abrasion resulting from rigid-soled shoes. However, such course-pitch micro-bumps would not provide adequate protection from small abradants as shown in the left hand sequence in FIG. 11. Printing micro-bumps at finer pitch (e.g. 10 micron diameter dots on 1 mm pitch) would provide enhanced protection of the surface from a wider range of abradants, such as objects that can span across more than two dots. To minimize the impact of a large number of dots on the optical transmission of the coating, the material used for the glass dots should be optically transparent, with minimum absorption in the UV and visible wavelengths, a low index of refraction and a small diameter. The pitch of the bumps also needs to be optimized to insure optimized water collection and self-cleaning efficiency. As discussed elsewhere in this application, the pitch may be sufficiently large to avoid liquid droplets from bridging between adjacent hydrophilic regions before roll-off as well as sufficiently small to maximize water collection and self-cleaning efficiency.

In one example, enamel from Reusche & Co. was used. A fine tipped applicator was used to apply dots of enamel on a soda-lime glass microscope slide. The coated slide was heated in a furnace until the enamel melted and the slide was allowed to cool on the bench. The glass micro-bumps were optically clear with a convex lens shape that measured approximately 1 mm in diameter. They were placed on a 5 mm pitch with rows staggered to form a 2-dimensional hexagonal array. Onto this micro-bumped glass substrate, a layer of FEP resin was laminated at 650° F. for 15 minutes. The sample was allowed to cool to 165° C. for 30 minutes and then the excess FEP resin was peeled away. The resulting surface exhibited excellent superhydrophobic properties. The contact angle of 20 microliter water droplets was 149±1° and the sliding angle was 24±2°. These properties are essentially the same as those formed from FEP by peeling on a planar glass substrate.

Other methods can be used to form micro-bumps onto the rigid (e.g. glass) substrate. In one example, glass particles of the appropriate size can be bonded to the glass substrate using a sol-gel process. Small particles dispersed in a sol were shown to strongly adhere to glass. For particles that do not readily react with sol-gel, such as CaF₂ particles, adhesive could be used to bind particles to the glass surface. Using CaF₂ particles is advantageous because the low index of refraction of the particle will reduce reflections from the surface. Moreover, CaF₂ is essentially not soluble in water and so it will exhibit long-term chemical stability. Other low-index water stable compounds that could be used include: MgF₂, fluorinated tin oxide and porous silica particles.

These particles can be applied using a variety of methods, similar to those methods used to dispense particles of glass enamel including solvent spray, electrostatic spray, dusting techniques, dip coating, printing, dispensing, etc. The particles can be aligned in ordered arrays or randomly distributed on the surface. Typically, it is helpful to use an adhesive to bind the particles onto the substrate because the horizontal shear forces that develop during polymer lamination may sweep the particles off the surface forming agglomerates that scatter light and/or leaving regions unprotected.

Another approach for increasing the abrasion resistance of transparent polymer coatings is by embedding rigid particles into the polymer coating itself. In one embodiment the diameter of the particles is at least as large as the coating. The particles should be smaller than 100 times the thickness of the coating, and more preferably, smaller than 10 times the thickness of the coating, and more preferably smaller than 1.5 times the coating thickness. The particle diameters can be less than the coating thickness and still provide some abrasion resistance to the overall coating. If the particles extend above the average coating thickness, they will provide abrasion resistance to the overall coating protecting the superhydrophobic properties as well as the overall coating thickness. If the particle diameters are less than the average coating thickness, they will provide abrasion resistance to the coating, but not provide protection of the fine-scale surface features that result in superhydrophobicity.

The index of refraction of the particles should be as close to the polymer as possible to minimize scattering of light at the particle-polymer interface. For example CaF₂ (index of refraction=1.43) and MgF₂ (index of refraction 1.38) would be good candidates as these materials are insoluble in water, optically transparent and have an index of refraction that closely matches fluoropolymers.

Glass particles may be easier to obtain with the desired dimensions and have a lower density, but have a higher index of refraction. The lower density of the glass particles is advantageous because they can remain dispersed in a fluid carrier for a longer time before settling under gravity. Glass particles may prove sufficient if scattering at the polymer-particle interface is of lesser concern. Alternatively, the concentration of glass particles, which are comparable in diameter to the thickness of the polymer coating, can be kept low to minimize the impact on the optical transmissivity of the coating. For example, the spacing between particles in the coating can be kept to a distance less than 10 microns, or less than 100 microns or less than 1000 microns. As the concentration of particles decreases, the impact on abrasion resistance will decrease, but the impact on % Transmission will be minimized. Alternatively, the composition of the particles can be selected so as to obtain the desired refractive index. In one example, the particles could be made of a porous glass to lower the refractive index and so further reduce reflections at the air-particle interface, or the particle-polymer interface if a low index of refraction polymer is used.

In one embodiment, particles with an average diameter that is less than the coating thickness are used. Particles made from glass, or other materials with an index of refraction that is higher than the polymer matrix, but equal to or lower than the index of the glass substrate, would be suitable if these particles were small in diameter (e.g. less than ¼ wavelength of incident light) and/or the particles were constrained to be located near the interface with the glass substrate. By isolating such particles near the glass-fluoropolymer interface, the transition between the polymer and glass substrate would have a graded-index of refraction and thus reduce reflections at the fluoropolymer-glass interface.

When the particles are comparable in diameter to the wavelength of light, the concentration of particles must be limited to minimize light scattering. This constraint is especially true when there is a large difference in refractive index between particle and polymer matrix. Agglomeration of particles in the polymer should be avoided as such particle agglomerates would further increase scattering of incident light and reduce overall optical transmission through the coating.

The rigid particles can be dispersed into the polymer film before it is laminated onto the rigid (e.g. glass or metal) substrate. Due to the high melt viscosity and low solubility of many fluoropolymers, a high sheer mixer, such as an extruder, would be necessary to achieve adequate dispersion. After lamination, the particles would be randomly dispersed in the polymer coating.

An alternative approach is to dispense the particles onto the surface after the neat polymer has been coated onto the rigid substrate. Particles can be dispersed in solvent and printed onto the polymer coated substrate in any arbitrary array or pattern. For example, small regions of particles (dots) could be dispensed in a square array on the polymer surface. Ideally, the dots would be comprised of a single particle with a diameter ranging in size from half the thickness of the polymer film to double the thickness of the polymer film, although particles smaller or larger could still be effective at resisting abrasion. Particles less than half the thickness would have the advantage that they would scatter light less effectively because of their small size (e.g. less than the wavelength of visible light), however they would be less effective at resisting abrasion. Small particles that are fully embedded in the polymer film would have a minimal effect on abrasion resistance until the upper portion of the polymer is abraded away to reveal the harder particle. Also if the particles are sufficiently small, they could be easily removed when adjacent polymer is abraded away. Larger particles could also be problematic as they would scatter light more effectively. Also, if the particles are much larger than the film thickness, they will not be well anchored into the polymer and thus more easily removed during abrasion.

The particles would be dispersed in a carrier liquid. Surfactants, such as Pluronic non-ionic surfactants manufactured by BASF, for example F108, may be necessary to maintain the particles dispersed in the liquid and prevent particle-particle agglomeration. Smaller and lower-density particles, such as 0.3 micron SiO₂ particles would be better suited for such dispersions because of their relatively small size and lower density compared to the alkaline metal compounds (CaF₂ and MgF₂) mentioned above. Particles with smaller sizes and with densities approaching the density of the carrier liquid would be better able to stay in suspension and not settle under gravity. The addition of a thickening agent, such as hydroxyethyl cellulose or sodium alginate hydrogel may be necessary to prevent settling of higher density particles. Such soluble polymers increase the effective viscosity of the liquid and so slow the settling of dense particles. These thickening agents are also advantageous as they will decompose under the temperatures utilized for lamination, forming volatile gases that escape from the system. Continuous agitation of the solution would further retard or prevent particle settling.

The concentration of the particles would be kept low and the volume of the dispensed droplet would be controlled such that one droplet would, on average contain a small number of particles and more preferably one single particle. Because of the random nature of the distribution of particles in solution, the concentration of particles would be adjusted such that more than one particle would theoretically be contained in a droplet. In this way, the number of droplets containing zero particles would be minimized without excessively increasing the number of droplets containing two or more particles.

The particle dispersion could be dispensed using standard techniques such as gravure printing, syringe dispensing, or single droplet dispensing. Alternatively, a random placement of particles could be dispensed on the surface using a fluidized bed either alone, or in combination with a spray gun or an electrostatic spray gun.

The particles would be dispensed on the surface—either randomly or in an ordered array. On average, the distance between particles would be as far apart as possible to minimize loss of light from scattering, but sufficiently close together to minimize the deleterious effects of abrasion. The average distance between particles would be determined by the application requirements as discussed elsewhere in this disclosure. Overall, the surface area covered by these particles would be less than approximately 10% of the surface.

After dispensing of particles, the droplets would be dried to remove the carrier liquid leaving the isolated particle (or small number of particles) on the surface of the polymer coating. If a thickening agent was added, it may be necessary to heat the surface to higher temperatures to decompose the thickening agent as a separate step.

To imbed the particles into the underlying polymer coating, a lamination step with the simultaneous application of heat and pressure, is used. An inert release layer, such as KAPTON® polyimide would be placed on top of the particles on the surface of the polymer coating and heat and pressure applied. This would result in a thin, optically transparent coating on the surface of the glass, or other rigid substrate. The coating would have antireflective properties from the low index of refraction (i.e. an index of refraction between glass and air) of the polymer coating. The coating would have stable anti-soiling properties because of the low surface energy of the fluoropolymer. In addition, the coating would be abrasion resistant because of the particles that become fully or partially embedded into the tough, high molecular weight polymer.

Alternatively, the polymer surface can also be made to be superhydrophobic. In this case, the thermally stable (e.g. glass) surface would be coated with a thin layer of polymer, such as a fluoropolymer. Abrasion resistant particles would be deposited on this coating as described previously. A second layer of the same fluoropolymer would be placed on top of the particle coated polymer layer. An inert release layer, such as KAPTON® polyimide would be placed on top of this added fluoropolymer and heat and pressure applied. The two fluoropolymer layers would fuse together during the lamination step. After cooling to the appropriate temperature, the second fluoropolymer layer would be peeled away from the surface (as described in: U.S. Patent Publication US2016/0332415) to reveal a nanotexture on the outer surface of the fluoropolymer coating. The nanotexture would result in high contact angles (greater than 150°) and low slip angles (less than 20°) with water and improved anti-soiling properties under certain conditions. Because of the particles embedded into the fluoropolymer coating, the resulting coating would also exhibit improved abrasion resistance compared to polymer coatings prepared without these particles.

Particle Loading to Increase Abrasion Resistance: In those cases where the index of refraction of the particles and polymer are sufficiently close that scattering at the polymer-particle interface is minimized, then the concentration of particles can be greatly increased without adversely affecting the optical properties of the coating. The abrasion resistance of the coating increases as the concentration of particles is increased. A combination of particle sizes may prove advantageous for increasing the abrasion resistance without excessively increasing the viscosity of the polymer and the ability to form good quality coatings. Small diameter particles, or even nano-particles could be used at these high concentrations so long as the quality of the polymer-particle interface is sufficiently high quality (i.e. good adhesion without air gaps formed) and the indices of refraction are well-matched.

A high concentration of particles can be added to the polymer composite to increase the abrasion resistance, but care must be taken to avoid optical scattering losses. In one approach, the particles and the polymer would have nearly the same index of refraction. In this case, particle loading can be very high without excessive light being scattered at the particle-polymer interface. To have the lowest losses, the particle size should be below one-fourth the wavelength of light (e.g. less than 150 nm). If the index match between polymer and particle is sufficiently close, larger particles can be used. In this case, particles with diameters as large as or greater than the coating thickness, (for example the coating may be in the range from 150-1000 nm or greater) can be used. The particles can be dispersed in the polymer first by using a high-shear extruder. The particle-polymer composite can then be laminated onto the glass. The particles will be uniformly distributed throughout the polymer. Alternatively, the polymer can be deposited onto the surface of the glass first. A layer of particles can be deposited on the polymer coating and laminated into the polymer coating. Using this technique, the particle concentration will be largest on the surface of the polymer, which is the region that will be subjected to the greatest abrasion. Hydrophilic particle that are revealed on the surface will form nucleation sites for water condensation and promote self-cleaning properties in addition to abrasion resistant properties.

Abrasion resistant transparent coatings achieved by crosslinking: It is well known that polymer coatings exhibit low abrasion resistance because the polymer molecules are soft relative to ceramics and metals. This is especially true for fluoropolymers. Previous studies have shown that increasing the crosslink density of a polymer increases the polymer's resistance to abrasion. To create a hydrophobic coating on glass, however, it is necessary to first deposit the polymer film using an appropriate method. For example, the technique described in U.S. Patent Publication US2016/0332415 can be used to form a transparent, anti-reflective and anti-soiling surface on a glass substrate. Other techniques may also be applicable. It is preferable to apply the polymer to the substrate first, while the polymer is a thermoplastic. Once the coating has been applied to glass, the thin polymer coating can be crosslinked to increase its abrasion resistance. In the case of U.S. Patent Publication US2016/0332415, the polymer is applied to the substrate under heat and pressure, allowed to cool below the crystalline melt point, and then the excess polymer is peeled away. Crosslinking would be performed after cross-linking such that the fine-scale nanofibrils are preserved and toughened during the cross-linking reaction.

The polymer can be crosslinked using chemical means by incorporating a cross-linking agent into a polymer that has been modified with the appropriate functional group(s) such as alkene or alkyne termination. Because cross-linking should be avoided during lamination to ensure that the polymer coating is both thin and has the appropriate nano-texture, the incorporation of chemical cross-linking agents may be challenging as the cross-linking reaction must occur only after the polymer coating is fully formed. Typical cross-linking agents are heat activated and so will cure the polymer during the lamination step. As a result, the peeling step may not successfully form a thin and/or nano-textured surface. Other types of chemical cross-linking agents may be used, such that the reaction is activated not by heat, but by actinic radiation, such as UV or e-beam. Exposure to this radiation after lamination and peeling will initiate the cross-linking reaction. Although chemical crosslinking may be a low-cost approach to increasing the abrasion resistance of the coating, there are several challenges to implementing this approach including: incorporation of reactive groups into the polymer chains; synthesizing a polymer-soluble cross-linking agent; dispersing the cross-linking agent uniformly into the polymer matrix; and developing a thermally stable chemistry that will not form crosslinks during the lamination and peeling steps.

An alternative approach is to use actinic radiation in combination with a commercially available thermoplastic resin. It has been shown that deep UV, x-ray, e-beam, gamma-ray, etc. can form cross-links in a wide variety of polymers, including fluoropolymers. The increased cross-link density was shown in published papers to increase the abrasion resistance of the polymer surface. Using actinic radiation has a significant advantage as the radiation does not significantly expose the polymer surface to heating. As a result, the morphology of the nanostructures formed on the surface will not be adversely affected.

For example, to fabricate an abrasion resistant FEP coating on glass, an FEP layer would be thermally laminated to a glass surface at a temperature above the melt point of the FEP polymer (e.g. 310° C.). After lamination, the sample would be cooled to a temperature below the melting temperature (e.g. 160° C.) such that the polymer is sufficiently rigid. The excess polymer would be peeled from the substrate leaving a thin (about 300 nm), nanotextured FEP coating on the glass. The coated glass coupon would then be exposed to radiation (e.g. 10-30 Mrad of gamma rays) so that the surface becomes crosslinked and more abrasion resistant.

The crosslinked polymer coating can be formed on planar glass substrates, glass substrates with micro-bumps, curved substrates (e.g. lenses) or any combination of these substrates. Particles may also be included in the polymer before crosslinking. The combination of particles and cross-links would provide enhanced abrasion resistance compared to either method alone.

System for cleaning Transparent, Anti-Reflective and Anti-Soiling coatings: Anti-soiling coatings are effective at preventing dirt and dust particles from becoming bonded to the glass surface, thus facilitating cleaning. Moreover, hydrophobic coatings in general and superhydrophobic coatings in particular have been shown to require much less water to remove soil from their surfaces when compared to untreated glass (An Anti-Reflective and Anti-Soiling Coating for Photovoltaic Panels, Xu, Q. F.; Zhao, Y.; Kujan, E.; Liu, J. C.; Lyons, A. M., TechConnect World Technical Proceedings 2015, Jun. 14-18 2015, paper 413.). A single water droplet is able to slide down the coating, imbibing dust and dirt particles along the way. Because many solar arrays are being installed in arid climates, water for cleaning is expensive and difficult to obtain. Thus a system that uses a small amount of water to clean the photovoltaic panels is beneficial as it conserves this precious resource. Moreover, a system in which the water can be recovered and re-used is even more beneficial as it further minimizes the cost, labor and time required to replenish the source of water for cleaning. Some cleaning systems spray water onto the solar panels. This is not desirable as the small airborne droplets readily evaporate resulting in significant losses of water as well as the potential for salt particle formation that may further aggravate cleaning requirements.

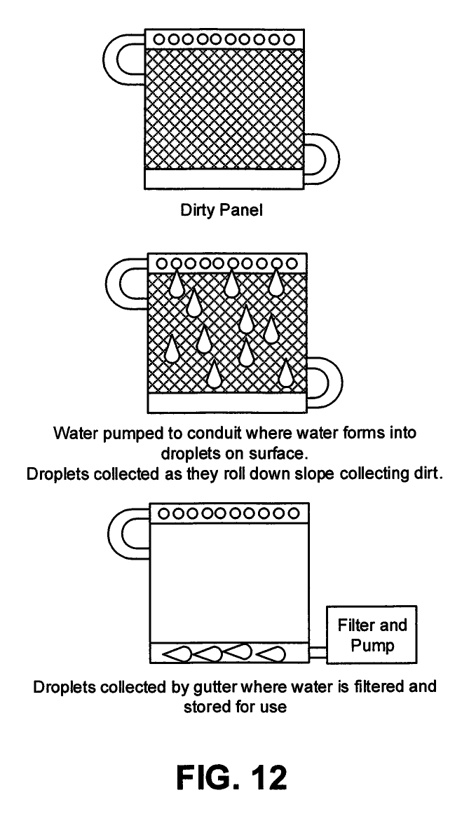

Stationary tube creating flow of water droplets: A system for cleaning glass with a minimal amount of water is shown in FIG. 12. In this system, a superhydrophobic conduit is used to generate an array of individual droplets that slide along the outer glass panel of a PV module such that the droplets imbibe dirt and dust, leaving the panel surface clean. The droplets are collected in a gutter at the end of the panel which transports the water to a sink. The water in the sink can then be processed through a series of filters to remove the dust and dirt. The cleaned water can then be stored until the next cleaning cycle when it is pumped to the superhydrophobic conduit and the cleaning process repeated.

The conduit is comprised of an inner and outer surface. The inner surface is made from a material that is impermeable to water. The outer surface is treated to be superhydrophobic. To produce the outer superhydrophobic surface, any of a number of different processes can be used. For example, the processes disclosed by Lyons and Xu in U.S. Pat. No. 9,040,145 issued May 26, 2015, entitled “Polymer having a superhydrophobic surface” would produce a flexible polymer substrate with an inner hydrophobic polymer surface (e.g. polyethylene or polyvinylidene fluoride) and an outer superhydrophobic polymer surface with hydrophobic nanoparticles partially embedded into the outer polymer surface.

To create the droplets, holes are made through the conduit thereby connecting the inner and outer surfaces. The holes can be punched before forming the conduit, or the holes can be created after the conduit is formed. The holes are placed in an array such that the droplets emanating from the conduit will be able to cover the entire surface of the solar panel underlying the conduit. The array of holes may be linear, or staggered. Many different spacing of holes is possible. In one preferred embodiment, the hole diameters and hole spacing are designed such that adjacent droplets do not coalesce before dropping onto the panel surface. The holes may be circular, forming a nearly spherical droplet, or they may be slits such that an oblong droplet is formed.

The advantage of forming a superhydrophobic outer surface on the conduit is that individual droplets will form at the holes and grow to a critical size, which is dependent on the size of the hole and the water pressure in the conduit. Once the critical droplet size is exceeded, the droplets will separate from the conduit and roll down onto the tilted glass panel. If the conduit is raised above the glass, the droplets will fall under the force of gravity and land on the panel. If the panel is coated with KLEANBOOST™, or similar hydrophobic coating, the droplets will roll or slide down the surface of the panel, imbibing dust and roll off the panel surface leaving the panel clean. The advantage of the superhydrophobic outer coating of the conduit is that the droplets will not spread across the conduit surface. Thus the droplets will drop directly onto the glass in known locations, pre-determined by the position of the holes. In this way, all of the water will be used to clean the panel; water will not be wasted by wetting the exterior of the conduit; and the entire panel surface can be cleaned. Without the superhydrophobic coating, the droplets could slide along the conduit and drop at any random location. As a result, some areas of the panel may not be cleaned. Moreover, water will not be sprayed into the air where it could evaporate before landing on the panel. Furthermore, the superhydrophobic outer coating reduces the need for small diameter orifices that can clog over time as well as high water pressures to force water through small orifices. Reducing pressure lowers the cost of pumps as well as the potential for pump failures.

The lower gutter can also be made from a superhydrophobic material such that the inner surface is superhydrophobic. In this way, water will not be retained on the gutter, thereby increasing the efficiency of the water collection system and reducing water losses due to evaporation.

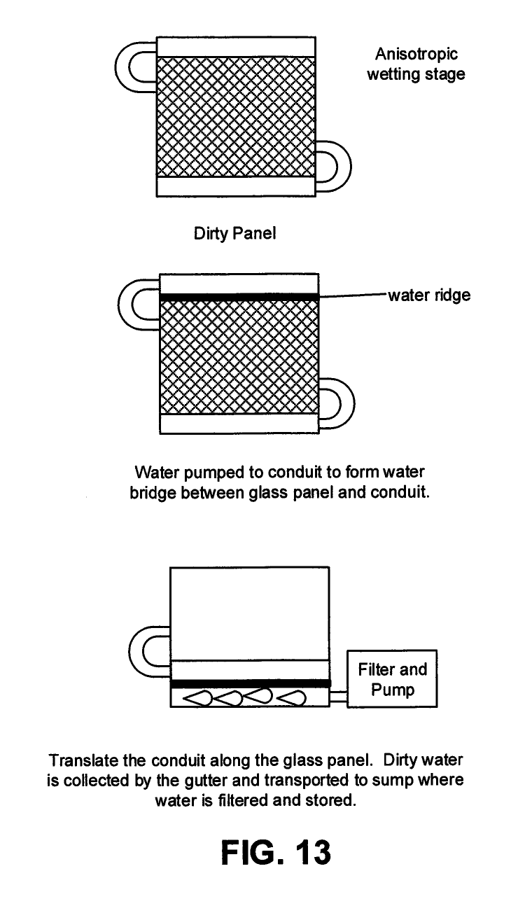

Translating superhydrophobic liquid water ridge: An alternative system is shown in FIG. 13. In this system, a conduit with a stage is used to generate a ridge of liquid water between the conduit and the glass panel. The conduit can be translated across the outer glass panel of a PV module such that the water ridge imbibes dirt and dust, leaving the panel surface clean. The water ridge is collected in a gutter at the end of the panel which transports the water to a sink. The water in the sink can then be processed through a series of filters to remove the dust and dirt. The cleaned water can then be stored until the next cleaning cycle when it is pumped to the conduit and the cleaning process repeated.

In this embodiment, the water ridge formed on the specially designed stage remains attached to the conduit as the conduit is translated across the glass; individual droplets are not released. The gutter may be designed with a wiper such that the water ridge containing the collected dirt and dust is displaced from the stage of the conduit and transferred into the gutter. Alternatively, the water pressure is increased in the conduit when it is positioned above the gutter, thereby displacing the water ridge into the gutter and leaving the stage with a clean ridge of water for the next cycle of cleaning. A ridge of water ensures that the entire panel is cleaned. Alternatively, an array of stationary droplets, especially a staggered array of two or more rows of openings, could also be used.

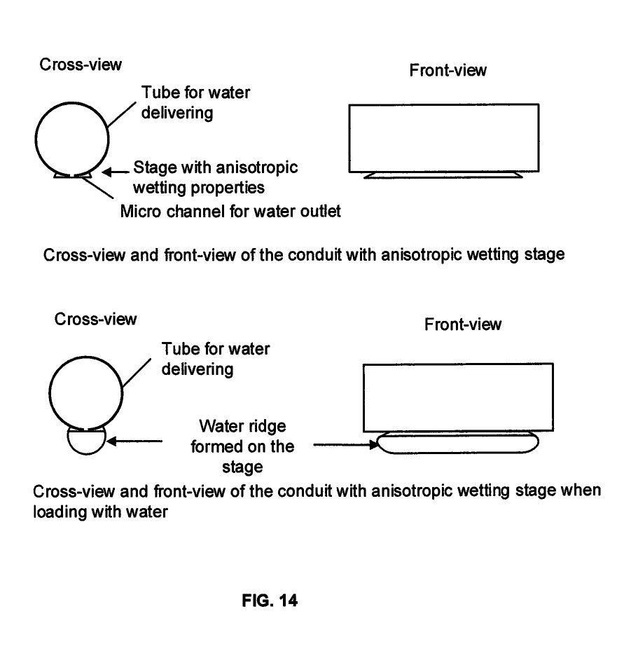

The detailed structure of the conduit with the stage is shown in FIG. 14. A continuous microchannel is used to connect the top surface of the stage to the interior of the conduit. The top surface of the stage is the base of the water ridge, and could be either hydrophobic or hydrophilic. The surface of the stage is preferably hydrophilic with a CA less than 90°, and more preferably less than 60°, and more preferably CA less than 30°. The stage may have undercut edges to prevent the contact of the water ridge to the surface of the conduit. The water ridge may have a thickness of less than 2.5 mm, so the water surface tension can balance gravity and prevent water from dripping off the stage. The shape of this ridge can assume different shapes, including the shapes described in U.S. Patent Publication US2017/0298314.

Self-Cleaning surfaces that are also Transparent, Anti-Reflective, Anti-Soiling and Abrasion Resistant: In many environments, dew forms on a glass surface during the early morning. In many cases, especially when the glass panel is not treated with a coating, the liquid water that condenses on the surface can initiate a chemical reaction between the glass and dust particles, forming an adhesive bond between the two as the water dries in the sun. Over repeated cycles of condensation (dew) and sunshine, the dust becomes especially difficult to clean away with water. In many cases, abrasive washing equipment, such as strong sprays and brushes cannot remove such cemented dust particles.

On a hydrophobic or superhydrophobic treated glass surface, condensation may also lead to undesirable adhesion of dust particles to the surface. Dew droplets are typically small, less than 2 mm in diameter, and so there may not be sufficient gravitational force (e.g. too low a tilt angle) for the condensed water droplets to roll off the surface. Once the weather conditions change, the condensed dew droplets will evaporate and leave a small deposit of dust at the location where the droplet evaporated. The dust in this deposit becomes concentrated and consolidated, making the deposit more difficult to remove during a rain or cleaning event, especially after repeated condensation cycles.

To alleviate this problem of dust adhesion, as well as to use the condensed water to help clean the panel, an array of hydrophilic regions can be formed on the hydrophobic/superhydrophobic coating. It is well known that water vapor will preferentially condense on a hydrophilic surface as opposed to a hydrophobic surface. This is because the water molecules impinging onto a hydrophilic region interact strongly with the surface and so are more likely to adhere. A water layer is the most hydrophilic surface that a water molecule can encounter, thus as water begins to condense, the condensation rate will accelerate. Water may also spontaneously condense on a hydrophobic surface to form a small droplet. However, these droplets will grow more slowly when adjacent to a hydrophilic region because of the Laplace pressure of the small droplet. The smaller the droplet, the greater the curvature. On a highly curved surface, the liquid water molecules located on the surface will have fewer nearest neighbors compared to a molecules located on the surface of a larger diameter droplet. As a result, water molecules will volatilize at a greater rate on a small droplet than on larger diameter droplets. Over time, the water in smaller droplets will be scavenged by the larger droplets.

Because of these mechanisms, the droplets on the hydrophilic regions grow to be much larger than on the hydrophobic regions. See for example: Mondal, B.; MacGiollaEain, M.; Xu, Q. F.; Egan, V. M.; Punch, J.; Lyons, A. M., Design and fabrication of a hybrid superhydrophobic-hydrophilic surface that exhibits stable dropwise condensation, ACS Appl. Mater. Interfaces, 2015, 7 (42), pp 23,575-23,588. Once the droplets grow above a critical size, they will roll, or slide, off a titled surface. The rolling droplets will imbibe dust and dirt, leaving the surface clean as described previously.

The critical size for roll-off depends upon the condensation rate, diameter of the hydrophilic spot as well as the tilt angle of the panel as discussed in Mondal 2015. Larger diameter spots will take longer to grow to critical volume, but will use lower tilt angles to slip down the panel. The density of spots will need to be optimized depending upon hydrophilic diameter, tilt angle and condensation rate. Hydrophilic spots that are too densely packed together will utilize longer times before any of the droplets reach critical volume. If the amount of dew/condensation is limited, the size of the droplets may never reach critical size and so cleaning will not be achieved and dirt will build-up on the hydrophilic regions. However, if the pitch between hydrophilic spots is too large, then it will be difficult to clean the entire panel. To help ensure that the entire panel is cleaned effectively, it would be advantageous to create staggered arrays of hydrophilic spots, similar to the staggered array of holes in the superhydrophobic conduit.

There are several approaches that can be used to create the hydrophilic regions. In one approach a hydrophobic coating is applied to the glass and arrays of sharp, stiff points are used to scratch away the coating revealing the underlying hydrophilic glass. Other means that are known in the art can be used to selectively remove the coating including other mechanical tools (e.g. drill bits, abrasive bits/tools, etc.) or beams of high-energy radiation such as a laser beam of a wavelength of light that can be readily absorbed by the coating material. Because many coatings are optically transparent, the lasers would be of a wavelength outside the visible spectrum such as: X-ray, UV or Infrared-red. The precise wavelength will depend upon the absorption properties of the coating with the greatest efficiency occurring when the coating strongly absorbs the light. The light may not have to completely remove the polymer to reveal the underlying hydrophilic substrate. Exposure of the surface to sufficiently energetic radiation in air or oxygen ambient will cause the selective oxidation of the coating in the exposed area. Photo-oxidation of most organic materials (e.g. polymers) will create polar, oxygen-containing groups, such as ketones and carboxylic acids. These functional groups are hydrophilic and will preferentially nucleate the condensation of water vapor.

Another approach to creating hydrophilic regions in a hydrophobic or superhydrophobic coating on a rigid substrate (e.g. glass substrate) is by including an array of glass micro-bumps on the rigid substrate, as described earlier in this document. As shown in FIG. 11, abrasion of such a surface will selectively remove the coating from the raised areas exposing the underlying hydrophilic substrate, while the coating remains undamaged between bumps. In this way, both abrasion resistance and condensation enabled cleaning is achieved.

Another approach to fabricating hydrophilic regions in a hydrophobic coating is to incorporate hydrophilic particles into the coating. The particles can be partially embedded into the surface and partially exposed. To fabricate this type of surface, the particles would be dispensed into an array as previously described. The particles could be dispersed in a solvent and printed or dispensed onto the coated surface. Alternatively, the particles could be sprayed onto the surface using a solvent carrier (e.g. paint sprayer), or an electrostatic gun where no solvents are needed, or other appropriate methods. After the particles are deposited (and any solvent dried), a release layer is placed over the surface and the coating is laminated under heat and pressure so that the particles become partially embedded into the coating. If the particle diameters are smaller than the coating thickness, care must be taken to apply an amount of heat and pressure that is sufficient to partially embed the particles into the polymer coating. Excessive heat and pressure would cause the particles to become fully embedded. Alternatively, the particle diameters are greater than the coating thickness so that they protrude from the surface. Preferably, the particle diameters would be less than twice the polymer coating thickness to ensure that the particles are well adhered and cannot be easily removed by abrasion. Also, it would preferable if the index of refraction of the particles matched closely the index of refraction of the polymer matrix into which they are embedded.

Another approach is to disperse the particles in the polymer before the polymer is laminated onto the glass. After lamination, some particles will be incorporated into the polymer coating. Because many of the particles may be fully encapsulated by the polymer, thereby rendering their surfaces hydrophobic, the coating must be treated by a subsequent process to expose the particles to the air interface. This can be achieved by exposing the coating to abrasion; the polymer coating will be abraded away exposing the underlying particles. Alternatively, the coating can be exposed to radiation that is preferentially absorbed by the particles. The particles exposed to such radiation will heat and develop sufficiently high local temperatures to thermally decompose the thin hydrophobic coating.

Another approach is to first apply a mask to hydrophilic glass. This mask can be in direct contact with the glass substrate or be a shadow mask. A hydrophobic coating is applied to the unmasked areas. The mask is then removed revealing uncoated, hydrophilic regions within an otherwise continuous hydrophobic coating

After forming the hydrophilic-hydrophobic polymer surface, the polymer matrix can be crosslinked as described above to increase the abrasion resistance of the coating.

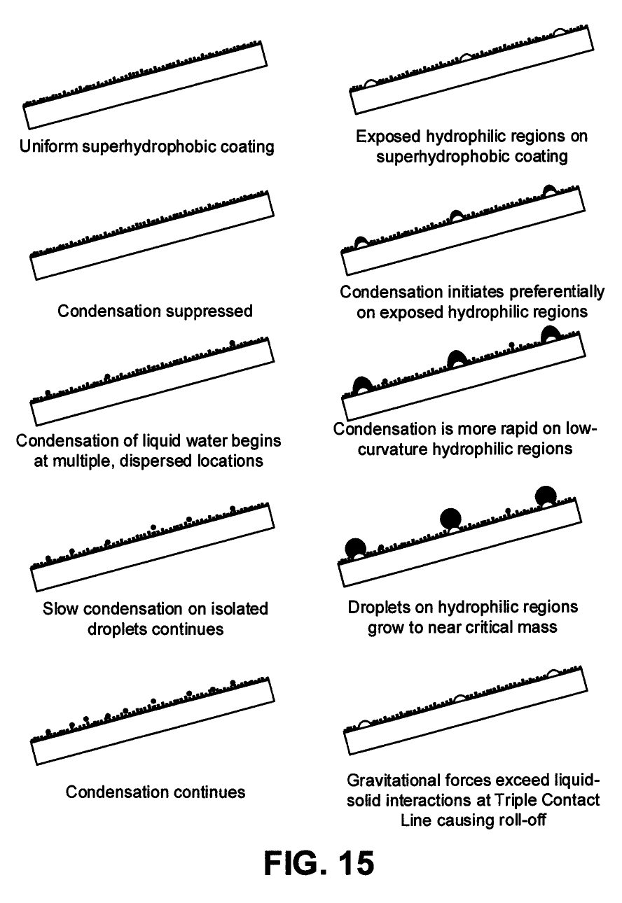

When exposed to a condensing environment, such as dew, water will begin to condense preferentially on the hydrophilic regions as shown in FIG. 15. These droplets will grow rapidly. Some droplets will nucleate on the hydrophobic portions of the surface, but these droplets will grow slowly, relative to the droplets that have condensed on the hydrophilic regions, because the water vapor pressure is relatively higher over the tightly curved small droplets and so will preferentially condense on the larger droplets. Eventually, the droplets that formed on hydrophilic regions will reach a critical diameter and roll off the surface, carrying away the small droplets, as well as dirt and dust, in its path. This leaves the surface clean and ready for a second cycle of dew to condense on the surface. Greater tilt angles will make this process more rapid.

This hydrophilic-hydrophobic coating could be used in conjunction with the cleaning systems that were discussed elsewhere and illustrated in FIGS. 13-15.

Enhanced Anti-Reflective performance: Most PV panels manufactured today include an AR coating on the exterior surface of the glass. This AR coating may be made from a wide variety of materials, including a porous glass made using a sol-gel process. However, these coatings are typically hydrophilic (i.e. neither hydrophobic nor superhydrophobic) and may collect dust which may adhere strongly to the glass, especially after cycles of moisture exposure. To further enhance the AR properties of this coating, as well as improve the anti-soiling properties, a transparent, AR and anti-soiling coating could be applied on top of this porous AR coating. For example, a coating as described in U.S. Patent Publication US2016/0332415 can be applied onto this AR coated glass. To obtain the best AR performance, the polymer used for the coating should have an index of refraction lower than the AR coating. Care must be taken when laminating the polymer to the glass so as not to damage the relatively fragile AR coating.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal language of the claims.

What is claimed is:

1. A hybrid substrate that has both hydrophobic and hydrophilic regions, the hybrid substrate comprising:
a planar substrate having a first surface;
a plurality of hydrophilic surfaces on the first surface, wherein each hydrophilic surface in the plurality of hydrophilic surfaces is spaced from adjacent hydrophilic surfaces by a hydrophobic surface with a pitch and the hydrophobic surface has a contact angle of at least 90°;
wherein the planar substrate, the plurality of hydrophilic surfaces and the hydrophobic surface are all optically transparent such that the hybrid substrate has at least 91% transmittance at 550 nm.

2. The hybrid substrate as recited in claim 1, wherein the plurality of hydrophilic surfaces have a first surface area and the hydrophobic surface has a second surface area, wherein a total surface area is the sum of the first surface area and the second surface area, the first surface area being less than or equal to 25% of the total surface area.

3. The hybrid substrate as recited in claim 1, wherein each hydrophilic surface has a surface area of less than 20 square millimeters.

4. The hybrid substrate as recited in claim 1, wherein each hydrophilic surface has a surface area of less than 1 square millimeter.

5. The hybrid substrate as recited in claim 1, wherein each hydrophilic surface is a continuous hydrophilic channel that has a width of at least 10 microns and less than 200 microns.

6. The hybrid substrate as recited in claim 5, wherein each continuous hydrophilic channel is parallel to adjacent continuous hydrophilic channels.

7. The hybrid substrate as recited in claim 1, wherein the pitch is between 0.5 mm and 10 mm.

8. The hybrid substrate as recited in claim 1, wherein the plurality of hydrophilic surfaces is below the hydrophobic surface.

9. The hybrid substrate as recited in claim 1, wherein the plurality of hydrophilic surfaces and the hydrophobic surface are coplanar.

10. The hybrid substrate as recited in claim 1, wherein the plurality of hydrophilic surfaces is above the hydrophobic surface.

11. The hybrid substrate as recited in claim 1, wherein the plurality of hydrophilic surfaces has a hydrophilic contact angle and the hydrophobic surface has a hydrophobic contact angle, and each hydrophilic surface is spaced from the hydrophobic surface by a boundary region that has a width and a variable contact angle between the hydrophilic contact angle and the hydrophobic contact angle and the hydrophobic contact angle changes over the width.

12. The hybrid substrate as recited in claim 11, wherein the width is at least 100 microns.

13. The hybrid substrate as recited in claim 1, wherein the plurality of hydrophilic surfaces and the hydrophobic surface define a coating thickness of less than 10 microns.

14. The hybrid substrate as recited in claim 1, wherein the plurality of hydrophilic surfaces and the hydrophobic surface define a coating thickness of less than 1 micron.

15. The hybrid substrate as recited in claim 1, wherein the planar substrate, the plurality of hydrophilic surfaces and the hydrophobic surface are all optically transparent such that the hybrid substrate has at least 94% transmittance at 550 nm.

16. The hybrid substrate as recited in claim 1, wherein each hydrophilic surface is circumscribed by the hydrophobic surface.

17. A hybrid substrate that has both hydrophobic and hydrophilic regions, the hybrid substrate comprising:
a planar glass substrate having a first surface and a second surface opposite the first surface;
a plurality of hydrophilic surfaces on the first surface, wherein each hydrophilic surface in the plurality of hydrophilic surfaces is spaced from adjacent hydrophilic surfaces by a hydrophobic surface with a contact angle of at least 90°;
wherein the planar substrate, the plurality of hydrophilic surfaces and the hydrophobic surface are all optically transparent such that the hybrid substrate has at least 91% transmittance at 550 nm;
a photovoltaic cell disposed proximate the second surface.

18. The hybrid substrate as recited in claim 17, wherein the planar glass substrate, the plurality of hydrophilic surfaces and the hydrophobic surface are all optically transparent such that the hybrid substrate has at least 94% transmittance at 550 nm.

19. A self-cleaning system for producing solar power, the system comprising the hybrid substrate as recited in claim 17, wherein the hybrid substrate is mounted at an angle of between 10° and 80° with the ground.

20. An optically transparent substrate comprising:
an optically transparent first substrate having a first surface with a plurality of optically transparent bumps, the plurality of optically transparent bumps having an average bump pitch, an average bump diameter and an average bump height, and an aspect ratio (height:diameter) given by a ratio of the average bump height to the average bump diameter;
an optically transparent semi-crystalline thermoplastic material having a coating thickness disposed on, and contiguous with, both the first surface and the plurality of optically transparent bumps, wherein the average bump height is greater than the coating thickness;
wherein the optically transparent semi-crystalline thermoplastic material comprises a fluropolymer having a water contact angle greater than 110°.
